(19) United States
(12) Patent Application Publication
(10) Pub. No.: US 2007/0093044 A1
(43) Pub. Date: Apr. 26, 2007

(54) Method of depositing a metal layer onto a substrate and a method for measuring in three dimensions the topographical features of a substrate

(75) Inventors: Bartolomeus Petrus Rijpers, Nuenen (NL); Hugo Augustinus Joseph Cramer, Eindhoven (NL)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 11/257,388

(22) Filed: Oct. 25, 2005

(51) Int. Cl. H01L 21/20

(52) U.S. Cl. 438/584

(57) ABSTRACT

A method of coating a substrate is disclosed in which a gas is activated using an electron beam. The coated substrate is then sliced using a particle beam to reveal, in cross-section, features of the resist. Those features of the resist are measured using a scanning electron microscope and a particle beam is used to take a slice of the substrate to reveal a new cross-section. This new cross-section is then measured using the scanning electron microscope and in this way a three dimensional map of the features may be built up.

### 1. FIELD

The present invention relates to a method of depositing a metal layer onto a substrate, particularly, for example, onto a substrate which has been processed in a lithographic apparatus. The present invention also relates to a method for measuring, in three dimensions, a topographical feature of a substrate.

### 2. BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

There are many instances in the field of lithography where it would be useful to measure the dimensions of topographical features present on a substrate which has been processed in a lithographic apparatus. For example, during the definition of a process for the production of features of a certain critical dimension it may be useful to be able to image those features such that the effect of variations in exposure and processing conditions can be visualized.

### 3. SUMMARY

Accordingly, it is desirable, for example, to provide one or more methods which may be used to measure a topographical feature of a substrate.

According to an aspect of the invention, there is provided a method for depositing a metal layer onto a substrate, the method comprising:

providing a flow of gas comprising a metal complex above a portion of the substrate;

activating the gas using a particle beam;

stopping the providing and activating for a period of time; and

repeating a cycle comprising the providing, the activating and the stopping.

According to an aspect of the invention, there is provided a method for measuring in three dimensions the topographical features of an area of a substrate, the method comprising:

presenting a first cross-section of the topography of the area to a measurement device;

measuring the first cross-section of the topography in two dimensions;

removing, using a particle beam, a slice of the substrate to expose to the measurement device a second cross-section of the topography of the area which second cross-section is substantially parallel to the first cross-section;

measuring the second cross-section of the topography in two dimensions;

performing the removing and the further measuring a plurality of times to build up a three dimensional map of the topographical features.

According to an aspect of the invention, there is provided a method for measuring in three dimensions the topographical features of an area of a top surface of a substrate, the method comprising:

placing the substrate in a chamber of an apparatus comprising an ion beam source and an electron beam source of an electron microscope;

providing a flow of gas comprising an organic platinum complex above a portion of the substrate;

activating the gas using the electron beam;

stopping the providing and activating for a period of time;

repeating a cycle of the providing, the activating and the stopping;

removing, using the ion beam, a portion of the substrate to expose to the scanning electron microscope a cross-section of the topography of the area;

measuring the cross-section of the topography exposed to the scanning electron microscope in two dimensions; and

performing the removing and measuring a plurality of times to build-up a three dimensional map of the topographical features.

According to an aspect of the invention, there is provided a method of characterizing a feature of a predetermined type on a substrate, comprising:

measuring a first two-dimensional cross-section of the feature at a first given position;

measuring a second two-dimensional cross-section of the feature at a second given position, the cross-sections at the first position and at the second position being substantially parallel; and

performing statistical analysis on results of the measuring.

### 4. BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 illustrates, in cross-section, a substrate which has been exposed in a lithographic projection apparatus and developed such that a pattern in a resist has been formed as topographical features in a top surface;

FIG. 2 illustrates a method of depositing a layer of metal onto a top surface of the substrate of FIG. 1;

FIG. 3 illustrates a substrate which has been coated in metal;

FIG. 4 illustrates schematically a method of measuring the dimensions of the topographical features in three dimensions;

FIG. 5 illustrates a scanning electron microscope (SEM) micrograph of the top surface of a substrate;

FIG. 6 illustrates typical measurements which might be taken of the cross-section of the topography; and

FIG. 7 illustrates a result of the characterization technique.

### 5. DETAILED DESCRIPTION

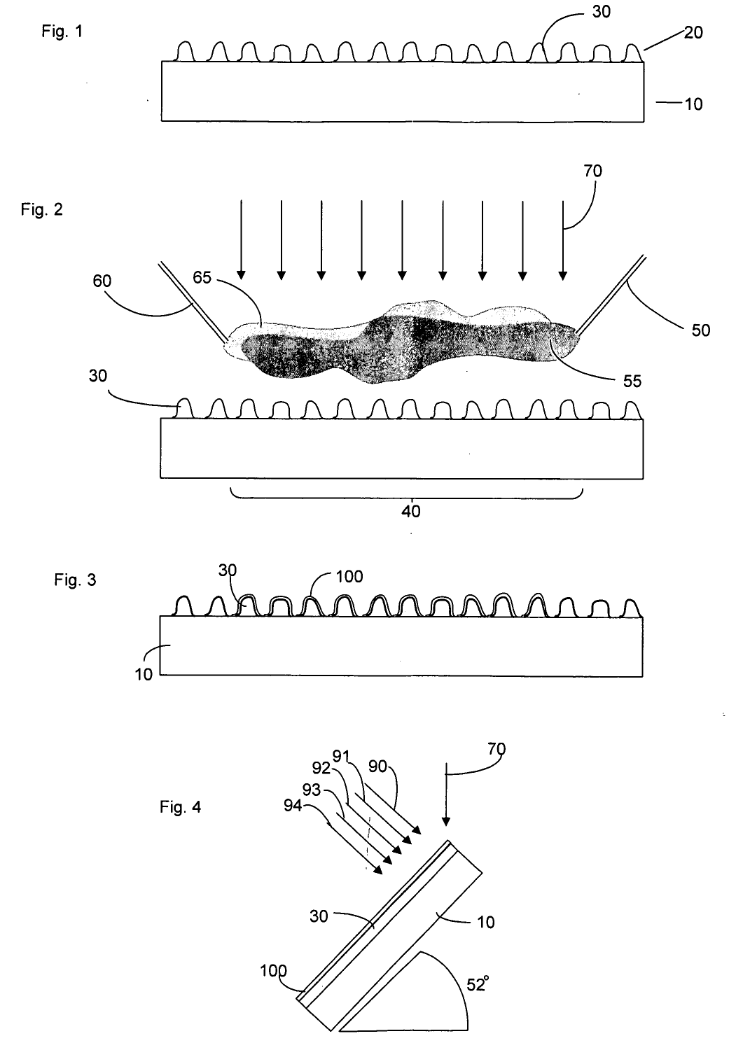

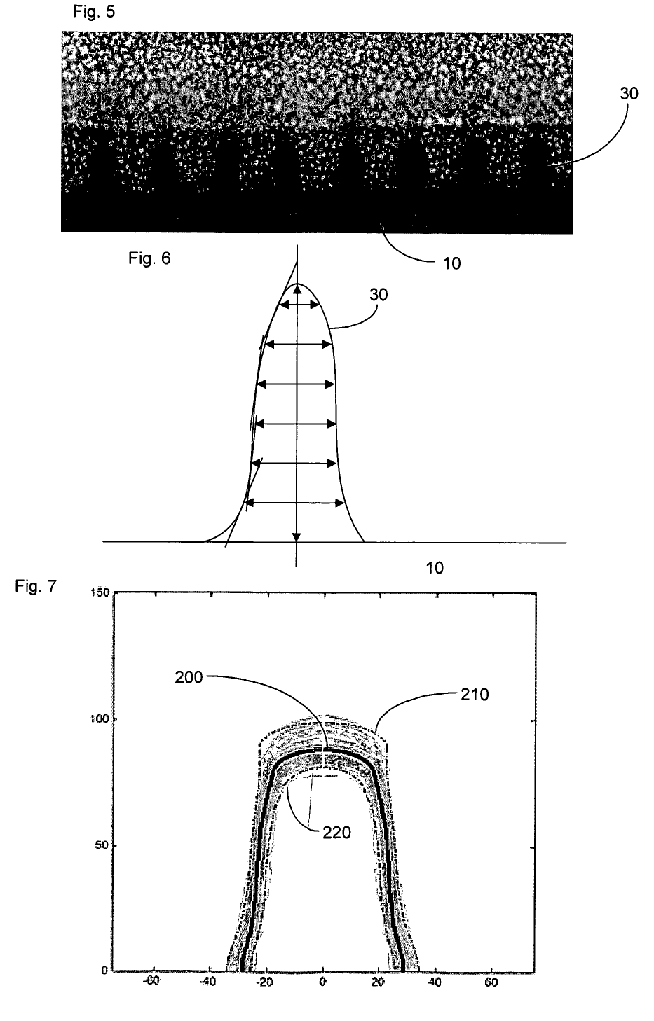

FIG. 1 illustrates, in cross-section, a substrate 10 on a top surface of which is a profile or topological pattern 20 comprising a plurality of lines 30. FIG. 5 illustrates a scanning electron microscope (SEM) micrograph taken after coating of the substrate using an embodiment of the method of the present invention. The white specs on the top surface are platinum. This coating may protect the resist from particle beams (described below) and enhance edge definition between the coating (conductive) and the resist or poly-silicon substrate (semi-conductive) which allows a high electron beam accelerating voltage to be used leading to higher resolution. Without a coating, a lower electron beam voltage likely should be used to prevent resist shrinkage and/or charging. This micrograph shows, in three dimensions, the lines 30 each running parallel to one another along the substrate. As can be seen, the lines 30 are not uniform. These variations in uniformity may lead to gross statistical inaccuracies in measuring a critical dimension from only one cross-section.

During quantification of the performance of a lithographic machine, a figure of merit is used. Often critical dimension uniformity is taken as this figure of merit. This is the total variance in critical dimension (e.g. line width) of features on the substrate. CD measurements of the substrate are typically performed using CD-SEM or scatterometry techniques. Before this qualification process the total process (reticle, exposure condition, resist-type, resist processing conditions, etc.) are typically optimized to be able to get the best CD uniformity possible. An embodiment of the invention may be used to select the best reticle, exposure, resist-type and resist process condition because it enables a three dimensional map of topographical features produced in a semiconductor manufacturing process to be measured.

Because of the roughness of the lines (as can be seen in FIG. 5), it isn't reliable to simply to run the measurement on a single cross-section because of statistical scatter. Thus, there is a need to generate multiple cross-sections and take an average of the cross-sections to get a statistically valid profile. Averaging of critical dimension measurements is one technique but this may not be used here since a profile is a three dimensional description of the line. Thus, a technique has been developed to give a two-dimensional representation of the line at a certain position along the length of the line. Then averaging of the two-dimensional profile is done along the length of the line.

First, a layer of conductive material, in an embodiment metal such as platinum, is deposited on the substrate so that the resist layer is covered with a thin film of the material (e.g., platinum). This protects the resist against subsequent exposure to particle beams and allows a SEM or a transmission electron microscope (TEM) to be used to image the resist.

The substrate is placed in a dual beam apparatus, e.g., a FEI IC3D 1275 machine which comprises both an ion beam source and an electron beam source. The electron beam source forms part of a scanning electron microscope.

Referring to FIG. 2, an area of interest 40 of the substrate is chosen using the scanning electron microscope. In an embodiment, during this procedure, the substrate is oriented substantially perpendicular to the direction from which the electron beam is coming. An area of approximately 5 μm by 5 μm is selected using the scanning electron microscope and the electron beam is scanned over that area. A precursor gas, which is activatable by a particle beam, is then introduced above the substrate and the precursor gas, once activated, can be used to coat the substrate with the desired conductive material (e.g., a metal such as platinum).

As is illustrated in FIG. 2, the precursor gas may be introduced above the sample using a gas injection system tubular nozzle 50 of about 0.7 mm diameter. A gas flux of about 8×10⁷ mol/cm²s is used. In the embodiment illustrated in FIG. 2, two nozzles 50 and 60 are present and two different precursor gases 55, 65 are introduced above the substrate. The precursor gases 55, 65 will be described in more detail below. An electron beam 70 of the scanning electron microscope (scanning the area of interest) is used to activate the precursor gas 55, 65 and this results in deposition of a layer of conductive material (e.g., metal) 100 over the topographical features of the substrate in the selected area 40.

FIG. 2 shows the electron beam 70 impinging on the substrate at 90°. In an embodiment, the electron beam may impinge on the surface at an angle such as a tilt of 52°. A tilt of the substrate or the beam of about 50° off vertical can be used, say between 30 and 70° off vertical.

In an embodiment, the precursor gas used is an organic metal complex which comprises organic matter chemically bonded to the metal to be deposited on the substrate. The electron beam 70 activates the precursor gas and thereby separates the metal from its organic complex i.e. the organic part is removed. The metal then deposits onto the area of interest. One suitable metal for coating is platinum and a suitable organic platinum complex is Epigrade PT10 platinum source for chemical vapor deposition (CVD) which is trimethylcyclopentadienyl platinum IV with the formula (CH₃C₅H₄)(CH₃)₃Pt, but other gases may also be suitable.

In an embodiment, the addition of a second precursor gas 65 may be beneficial but not essential. The second precursor gas may be a particle beam activated etchant gas such as a selective carbon mill comprising magnesium sulphate heptahydrate: MgSO₄O₄.7H₂O. It improves the edge transition between the photoresist and the platinum during the ion milling reaction described below and improves edge definition during SEM scanning measurement between the resist and the platinum.

In an embodiment, in order to get monolayer growth of platinum and minimize exposure to the electron beam, there is provided a cycle of providing gas and activating it followed by a period of time in which no activity takes place preceding another cycle of injecting gas and activating it using the electron beam 70. In an embodiment, an electron beam voltage of 750 volts is used and scanning for 23 seconds followed by a period of time during which nothing happens (i.e. the gas is not injected and the electron beam is switched off) of 50 seconds. In an embodiment, this cycle is repeated 24 times.

Values which may also work are a cycle repetition of at least 5 times, an electron beam voltage of at least 500V or at least 550 volts, or at least 700 volts and less than 5 kV and a time period of providing the gas and activating the gas of between 1 or 10 and 100 seconds, or between 10 and 40 seconds. The period of time during which nothing is done may be between 5 or 20 and 200 seconds, or between 40 and 80 seconds.

The above coating procedure results in a substrate as illustrated in FIG. 3 in which a layer of conductive material (e.g., a metal such as platinum) 100 has been deposited on the area of interest 40. The substrate is then arranged in the dual beam apparatus such that a focused ion beam 90 impinges on the top surface of the substrate at substantially 90° to the top surface. The ion beam is then scanned across the substrate to slice the substrate in a direction perpendicular to the lines 30.

A liquid gallium ion beam may be used which is scanned over the part which is to be removed. First the edge of the substrate is scanned with the ion beam scanning an area which overlaps the edge of the area covered in metal (e.g., platinum). Typical operating parameters may be a sputter rate of 0.3 μm³/nA·s, an overlap of −50% (i.e. the lines which are scanned are separated by half the nominal diameter of the ion beam), a dwell of 0.1 μs, a depth of 0.2 μm (for 150 nm resist lines). The length scanned may be 5 μm which gives a scan rate of 50 m/s. In an embodiment, overlap may be −150 to +150% or −30 to −100%. In an embodiment, the scan rate may be between 10 and 100 m/s.

The scanning electron microscope may then be used to measure the size and shape, as desired, of a plurality of the lines 30 in two dimensions.

In FIG. 4 it is illustrated that the electron beam 70 of the scanning electron microscope impinges on the cross-section of the substrate at 52° though this is not necessarily the case. The figure illustrates schematically a dual electron/ion beam machine. In this embodiment, the substrate is not rotated between being covered in metal (e.g., platinum), sliced by the focused ion beam and measured by the electron beam so that the electron beam impinges on the substrate slightly from above at an angle of 52°. However, the invention is not limited to this and the substrate may be rotated and/or translated between coating, slicing and measuring steps and can be at any angle to the particle beams.

As is illustrated in FIG. 4, after measuring of the two dimensional dimensions of the lines 30 a further slice is taken by passing the focused ion beam across the substrate again (by focusing on a different part or by moving the substrate). As is illustrated in FIG. 4, several slices can be taken by passing the focused ion beam a number of times across the substrate 90, 91, 92, 93, 94. When a slice is taken, an area is scanned which overlaps the edge of the area covered in metal. An area approximately 50 nm in thickness (i.e. a slice thickness of 50 nm) is scanned. The number of slices taken is dependent on the statistical aims of the measurement and the number of lines measured for each slice. Typically 5 lines would be measured for each slice and 18 slices would be taken giving 90 resist profiles to be measured. The whole process can be automated and run by a computer and the statistical results displayed in any way.

FIG. 6 illustrates one way in which the size and shape of a line 30 can be measured. A center line is drawn down the center of the line 30 and the thickness of the line 30 on either side is measured as illustrated. The height of the line 30 is also measured and it is possible to measure the gradient of the side walls of the line 30 at given intervals. This latter measurement is particularly useful in the identification and characterization of so called footing errors which are the widening of the line 30 close to the bottom of the line 30 where it meets the substrate.

As will be appreciated, taking these measurements of the same line 30 along a number of slices will build up a three dimensional picture of the shape of that line 30. Averaging out the measurements of the dimensions of a line 30 taken in two dimensions along the length of the line (i.e. averaging out each individual reading for each slice taken) will give a result which is the median of the shape and dimension of the line along its length. Also lines for the 10% and 90% percentiles can be drawn on the same graph showing how consistent the lines are in both height and width. FIG. 7 shows a plot in which the measured profiles of all 5 lines of each of 18 slices have been plotted and the median profile 200 and 10 and 90% percentiles 210, 220 have been superimposed. This powerful measurement and characterization technique allows the effect of changing resist to be easily visualised making selection of the best resist easier. Thus, the roughness of the lines which can be seen in FIG. 5 can be accounted for and statistically meaningful measurements can be made.

It has been described that the gas is electron beam activatable and that the measurements are made with an electron beam too. This is not necessarily the case and an ion beam may also be used.

The coating and slicing technique described above may also be used prior to making a slice for use in a transmission electron microscope (TEM). Such a slice will allow 90 or so lines 30 to be measured from one slice and statistically meaningful results can thereby be achieved.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

1. A method for depositing a metal layer onto a substrate, the method comprising:
providing a flow of gas comprising a metal complex above a portion of the substrate;
activating the gas using a particle beam;
stopping the providing and activating for a period of time; and
repeating a cycle comprising the providing, the activating and the stopping.

2. The method of claim 1, wherein the cycle comprising the providing, the activating and the stopping is repeated at least 5 times.

3. The method of claim 1, wherein the particle beam is an electron beam and the electron beam is accelerated by a voltage of at least 500V and less than 5 kV.

4. The method of claim 1, wherein the providing and activating are carried out for between 1 and 100 seconds per cycle.

5. The method of claim 1, wherein the period of time is between 5 and 200 seconds.

6. The method of claim 1, wherein the metal is platinum and the metal complex is an organic metal complex (CH₃C₅H₄)(CH₃)₃Pt.

7. The method of claim 1, wherein the gas further comprises a particle beam activated etchant gas.

8. A method for measuring the topographical features of a substrate using the method for depositing a metal layer onto the substrate according to claim 1.

9. The method of claim 8, comprising:
using a particle beam to remove a slice of the substrate; and
measuring the topographical features of the substrate with a measurement device.

10. The method of claim 9, wherein the topographical features on the slice are measured with a transmission electron beam microscope.

11. A method for measuring in three dimensions the topographical features of an area of a substrate, the method comprising:
presenting a first cross-section of the topography of the area to a measurement device;
measuring the first cross-section of the topography in two dimensions;
removing, using a particle beam, a slice of the substrate to expose to the measurement device a second cross-section of the topography of the area which second cross-section is substantially parallel to the first cross-section;
measuring the second cross-section of the topography in two dimensions;
performing the removing and the further measuring a plurality of times to build up a three dimensional map of the topographical features.

12. The method of claim 11, wherein the particle beam is an ion beam.

13. The method of claim 12, wherein the ion beam impinges on the substrate substantially at a right angle to the top surface.

14. The method of claim 12, wherein the ion beam is scanned over the substrate with a beam overlap of −150 to +150% or of −30 to −100%.

15. The method of claim 12, wherein the ion beam is scanned over the substrate at a rate of between 10 and 100 m/s.

16. The method of claim 11, wherein the measurement device is a scanning electron microscope.

17. A data set collected by a method of claim 11.

18. A method for measuring in three dimensions the topographical features of an area of a top surface of a substrate, the method comprising:
placing the substrate in a chamber of an apparatus comprising an ion beam source and an electron beam source of an electron microscope;
providing a flow of gas comprising an organic platinum complex above a portion of the substrate;
activating the gas using the electron beam;
stopping the providing and activating for a period of time;
repeating a cycle of the providing, the activating and the stopping;
removing, using the ion beam, a portion of the substrate to expose to the scanning electron microscope a cross-section of the topography of the area;
measuring the cross-section of the topography exposed to the scanning electron microscope in two dimensions; and
performing the removing and measuring a plurality of times to build-up a three dimensional map of the topographical features.

19. A method of characterizing a feature of a predetermined type on a substrate, comprising:
measuring a first two-dimensional cross-section of the feature at a first given position;
measuring a second two-dimensional cross-section of the feature at a second given position, the cross-sections at the first position and at the second position being substantially parallel; and
performing statistical analysis on results of the measuring.

20. The method of claim 19, wherein the first and second two-dimensional cross-sections are of different individual features.

21. The method of claim 19, wherein the first and second two-dimensional cross-sections are of the same individual feature.

22. The method of claim 19, comprising further measuring of a further cross-section of the feature at a further given position, the cross-sections at the first, second and further positions being substantially parallel and being of the same individual feature and/or comprising measuring a cross-section of a different individual feature.

23. A computer program product for controlling a computer comprising a recording medium readable by the computer, instructions recorded on the recording medium configured to direct the computer to carry out the method of claim 1.

24. A computer program product for controlling a computer comprising a recording medium readable by the computer, instructions recorded on the recording medium configured to direct the computer to carry out the method of claim 10.

25. A computer program product for controlling a computer comprising a recording medium readable by the computer, instructions recorded on the recording medium configured to direct the computer to carry out the method of claim 18.

26. A computer program product for controlling a computer comprising a recording medium readable by the computer, instructions recorded on the recording medium configured to direct the computer to carry out the method of claim 19.

27. A scanning electron micrograph of a substrate coated according to the method of claim 1.
